(19) United States
(12) Patent Application Publication
(10) Pub. No.: US 2005/0121738 A1
(43) Pub. Date: Jun. 9, 2005

(54) Contact etch resistant spacers

(76) Inventors: Calvin T. Gabriel, Cupertino, CA (US); Christopher F. Lyons, Fremont, CA (US); Marina V. Plat, San Jose, CA (US); Ramkumar Subramanian, Sunnyvale, CA (US)

Correspondence Address: RENNER, OTTO, BOISSELLE & SKLAR, LLP (AMDS), 1621 EUCLID AVE - 19TH FLOOR, CLEVELAND, OH, 44115-2191, US

(21) Appl. No.: 10/726,380

(22) Filed: Dec. 3, 2003

(51) Int. Cl. H01L 31/107

(52) U.S. Cl. 257/438

(57) ABSTRACT

An apparatus and a method of fabricating a semiconductor device including the steps of forming a gate dielectric layer on a semiconductor substrate; forming a gate electrode over the gate dielectric layer wherein the gate electrode defines a channel interposed between source/drain regions formed within an active region of the semiconductor substrate; and forming contact etch resistant spacers on sidewalls of the gate electrode and sidewalls of the gate dielectric layer, the contact etch resistant spacers are of a non-silicon oxide and a non-nitride material.

### TECHNICAL FIELD

The present invention generally relates to semiconductor devices having sidewall spacers. In particular, the present invention relates to contact etch resistant spacers.

### BACKGROUND

A conventional field effect transistor (FET) is characterized by a vertical stack on a semiconductor substrate. The semiconductor substrate is doped with either n-type or p-type impurities to form an active region in the semiconductor substrate. The vertical stack includes a gate dielectric and a gate electrode. The gate dielectric of silicon dioxide (SiOₓ gate dielectric), for example, is formed on the semiconductor substrate. The gate electrode of polysilicon, for example, is formed on the gate dielectric. The gate electrode formed on the SiOₓ gate dielectric defines a channel interposed between a source and a drain formed within the active region of the semiconductor substrate. The source and the drain are formed by dopant impurities introduced into the semiconductor substrate. Spacers of SiOₓ, for example, are formed on the sidewalls of the vertical stack.

A pervasive trend in modern integrated circuit manufacture is to produce semiconductor devices, e.g., FETs, having feature sizes as small as possible. Many present processes employ features, such as gate electrodes and interconnects, which have less than a 0.18 μm critical dimension. As feature sizes continue to decrease, the size of the resulting semiconductor device, as well as the interconnect between semiconductor devices, also decreases. Fabrication of smaller semiconductor devices allows more semiconductor devices to be placed on a single monolithic semiconductor substrate, thereby allowing relatively large circuit systems to be incorporated on a single, relatively small die area.

As semiconductor device feature sizes decrease, the thickness of the SiOₓ gate dielectric decreases as well. This decrease in SiOₓ gate dielectric thickness is driven in part by the demands of overall device scaling. As gate electrode widths decrease, for example, other device dimensions must also decrease in order to maintain proper device operation. Early semiconductor device scaling techniques involved decreasing all dimensions and voltages by a constant scaling factor, to maintain constant electric fields in the device as the feature size decreased. This approach has given way to more flexible scaling guidelines which account for operating characteristics of short-channel devices. A maximum value of semiconductor device subthreshold current can be maintained while feature sizes shrink. Any or all of several quantities may be decreased by appropriate amounts including SiOₓ gate dielectric thickness, operating voltage, depletion width and junction depth, for example.

As a result of the continuing decrease in feature size and the limited space of a semiconductor substrate, designers would like to form contacts as close as possible to the vertical stack. This leaves very little margin for error in the fabrication process. In some cases, the SiOₓ spacers of a FET may be partially etched during a contact etch step. In some of these cases, the partial etching of the SiOₓ spacers is increased due to a misalignment of a contact mask. As a result, the operation of the device will be degraded.

Therefore, there exists a need in the art for a spacer that is resistant to the etch species used in the contact etch step in order to inhibit the etching of the spacers of a semiconductor device, thereby allowing contacts to be formed as close as possible to the vertical stack.

### SUMMARY OF THE INVENTION

According to one aspect of the invention, the invention is a method of fabricating a semiconductor device including the steps of forming a gate dielectric layer on a semiconductor substrate; forming a gate electrode over the gate dielectric layer wherein the gate electrode defines a channel interposed between source/drain regions formed within an active region of the semiconductor substrate; and forming contact etch resistant spacers on sidewalls of the gate electrode and sidewalls of the gate dielectric layer, the contact etch resistant spacers are of a non-silicon oxide and a non-nitride material.

According to another aspect of the invention, the invention is a semiconductor device including a dielectric layer interposed between a gate electrode and a semiconductor substrate; and contact etch resistant spacers formed on sidewalls of the dielectric layer and sidewalls of the gate electrode, the contact etch resistant spacers are of a non-silicon oxide and a non-nitride material.

According to another aspect of the invention, the invention is a semiconductor device including a gate dielectric layer disposed over a semiconductor substrate; a gate electrode formed on the gate dielectric layer defining a channel interposed between source/drain regions formed within an active region of the semiconductor substrate; and contact etch resistant spacers formed on sidewalls of the dielectric layer and sidewalls of the gate electrode, the contact etch resistant spacers are of a non-silicon oxide and a non-nitride material.

### BRIEF DESCRIPTION OF THE DRAWINGS

FIG. 1 is a schematic cross-sectional view of a semiconductor device including contact etch resistant spacers in accordance with the present invention.

FIGS. 2-6 are schematic cross-sectional views of the semiconductor device including contact etch resistant spacers at intermediate stages of manufacture in accordance with the present invention.

FIG. 7 is a schematic flow diagram showing the basic steps in a process of making a semiconductor device in accordance with the present invention.

In the detailed description that follows, identical components have been given the same reference numerals, regardless of whether they are shown in different embodiments of the present invention. To illustrate the present invention in a clear and concise manner, the drawings may not necessarily be to scale and certain features may be shown in somewhat schematic form.

### DETAILED DESCRIPTION

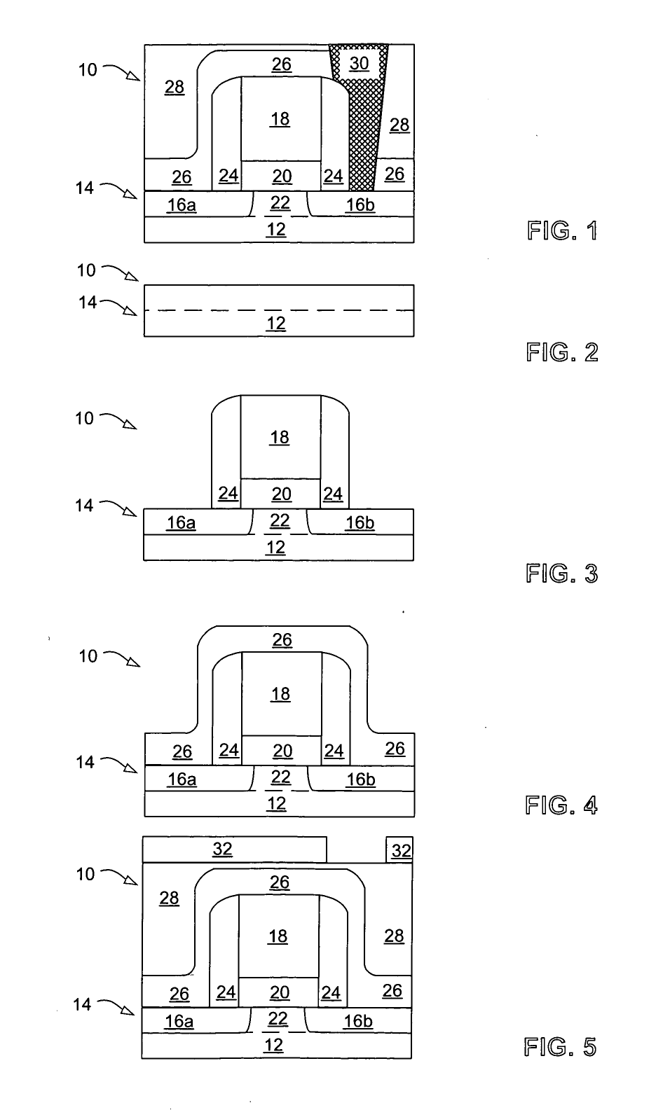

With reference to FIG. 1, a semiconductor device of the present invention is shown generally designated as 10. The semiconductor device 10 comprises a semiconductor substrate 12 having an active region 14. The active region 14 may have a thickness of between 800 and 1000 angstroms (Å). A gate electrode 18 is formed over a gate dielectric 20. The gate dielectric 20 is formed over the semiconductor substrate 12. Source/drain regions 16 (16a and 16b) are formed in the active region 14. The gate electrode 18 defines a channel 22 between the source/drain regions 16. The gate dielectric 20 and the gate electrode 18 form a vertical stack characteristic of a FET. Contact etch resistant spacers 24 are formed on the sidewalls of the vertical stack. A liner layer 26 may be formed over the contact etch resistant spacers 24. An interlevel dielectric (ILD) layer 28 or a passivation layer is formed over the device 10. A contact 30 is formed through a portion of the ILD layer 28 and a portion of the liner layer 26 to contact one of the source/drain regions 16 (Illustrated in FIG. 1 as source/drain region 16b). Isolation techniques that are known in the art may be used to electrically isolate the semiconductor device 10 from other semiconductor devices.

The contact etch resistant spacers 24 are formed of dielectric material that is resistant to the etchant species used in the formation of the contact 30. Thus, the contact etch resistant spacers 24 will be substantially unetched by the bulk chemistry typically used during the contact etch step to etch through the ILD layer 28 and the liner layer 26. The contact etch resistant spacer material is a non-silicon oxide and a non-silicon nitride material. For example, the contact etch resistant spacers 24 are made of one or more of silicon carbides, undoped silicon or other dielectric materials which are resistant to the etchant used to etch through the ILD layer 28 and, if used, the liner layer 26. The exemplary contact etch resistant spacers 24 may have total heights between 800 and 1200 angstroms (Å) and may have thicknesses of between 200 and 400 angstroms (Å), for example.

Although the contact etch resistant spacers 24 are shown as one layer, it should be understood that the contact etch resistant spacers 24 may have more layers. In one embodiment, the contact etch resistant spacers 24 have at least two layers of at least one of a first dielectric material and a second dielectric material. The second dielectric is formed over the first dielectric material. The second dielectric material is resistant to the etch species used in the contact etch step.

In the exemplary embodiment, as illustrated in FIG. 1, the channel 22 may be a p-type region and the source/drain regions 16 may be two N+ regions in the active region 14 of the semiconductor substrate 12. The channel 22 is interposed between the source/drain regions 16a and 16b. Alternatively, an n-type channel could be interposed between two P+ regions. Although the source/drain regions 16 are shown as respective deep implant regions, it should be understood that shallow extension regions could also be formed extending from the respective deep implant regions. The active region 14 may be predoped prior to the manufacture of the gate electrode 18 of the semiconductor device 10 with p-type dopings for n-type channel devices and/or n-type dopings for p-type channel devices.

The gate dielectric 20 interposed between the gate electrode 18 and the semiconductor substrate 12 is a single layer dielectric. However, the gate dielectric 20 could be a multi-layer dielectric. The gate dielectric 20 may be made of suitable gate dielectric materials, for example, SiOₓ or a gate dielectric material having a dielectric constant greater than SiOₓ (K=3.9). In this exemplary embodiment, the gate dielectric 20 is made of aluminum oxide (AlₓO_{y}). The gate dielectric 20 may have a thickness of between 50 and 100 angstroms (Å), for example.

The gate electrode 18 may be made of typical, well-known gate electrode materials, for example, polysilicon. The exemplary gate electrode 18 may have a thickness of between 750 and 1100 angstroms (Å).

Not shown in FIG. 1 are additional parts of a working semiconductor device, such as electrical conductors, protective coatings and other parts of the structure which would be included in a complete, working semiconductor device. These additional parts are not necessary to the present invention, and for simplicity and brevity are neither shown nor described. Nevertheless, how such parts could be added will be easily understood by those having ordinary skill in the art.

In one embodiment, the semiconductor substrate 12 is a bulk silicon semiconductor substrate. In one embodiment, the semiconductor substrate 12 is a silicon-on-insulator semiconductor substrate. In another embodiment, the semiconductor substrate 12 is a p-doped silicon semiconductor substrate. Suitable semiconductor substrates include, for example, bulk silicon semiconductor substrates, silicon-on-insulator (SOI) semiconductor substrates, silicon-on-sapphire (SOS) semiconductor substrates, and semiconductor substrates formed of other materials known in the art. The present invention is not limited to any particular type of semiconductor substrate.

The method of making the semiconductor device 10 having contact etch resistant spacers 24 is now described in detail with reference to FIGS. 2-7. FIG. 7 is a flow diagram 50 schematically presenting the steps of making the semiconductor device 10 of the present invention.

In the first step of the method of the present invention, shown in FIG. 7 as Step S52, the semiconductor substrate 12 is provided. The semiconductor substrate 12 is shown in FIG. 2, for example. The semiconductor substrate 12 may be any appropriately selected semiconductor substrate known in the art, as described above. The semiconductor substrate 12 may be subjected to implants to provide an active region 14 in the semiconductor substrate 12 as is known in the art. For instance, boron or indium may be implanted to form a p-type region or channel for an n-type device and phosphorous or arsenic may be implanted to form an n-type region or channel for a p-type device. An exemplary range of concentration of these dopings is between 1×10¹⁸ and 5×10¹⁸ atoms/cm³ for a p-type channel 22. The resulting structure is shown in FIG. 2.

Next in Step S54, the gate dielectric 20 is formed on the semiconductor substrate 12. The gate dielectric 20 is formed of a dielectric material. For exemplary purposes, the gate dielectric is formed of a dielectric material having a dielectric constant greater than the dielectric constant of SiOₓ, for example, AlₓO_{y}. The gate dielectric 20 of AlₓO_{y} may be deposited to a thickness between 50 and 100 angstroms (A). Then, the gate electrode 18 is formed on the gate dielectric 20. Initially, an undoped layer of polysilicon may be deposited on the gate dielectric 20. The polysilicon layer of the gate electrode 18 may be deposited to between about 1000 and 1500 angstroms (Å) thick. Following the deposition of the polysilicon layer, it may be polished back to a thickness of between 800 and 1200 angstroms (Å) thick. Next, the polysilicon layer is patterned to form the gate electrode 18. Following the patterning of the gate electrode 18, an implantation step may be done at this time to implant the polysilicon of the gate electrode 18. Alternatively, the polysilicon layer may be N+ predoped, for example.

Next, the semiconductor substrate 12 may be subjected to implants to produce the source/drain regions 16. The source/drain regions 16 may be formed by a main perpendicular implant. The main perpendicular implant is a relatively high energy, high concentration implant which is capable of producing the source/drain regions 16. Either boron, arsenic, or phosphorous may be used alone or in any combination as the dopant atoms. An exemplary range of implant dose of the perpendicular implant is between 1×10¹⁵ and 2×10⁵ atoms/cm². An exemplary range of concentration of these dopings is between 1×10²⁰ and 2×10²⁰ atoms/cm³ for the source/drain regions 16. The dopants may be selected from other dopant materials known in the art.

Although the source/drain regions 16 are shown as main implantation regions, it should be understood that extension implantation may be done in order to form extension regions as is known in the art. It should be understood that the formation of the source/drain regions 16 may take place before the formation of the gate electrode 18.

Next, the contact etch resistant spacers 24 are formed. First a contact etch resistant layer 24 is formed over the gate electrode 18, the sidewalls of the gate dielectric 20 and the surface of the semiconductor substrate 12 (not shown) in Step S56. The contact etch resistant layer 24 is formed of a dielectric material that is resistant to the etch species to be used in the formation of the contact 30. The contact etch resistant layer 24 may be deposited by chemical vapor deposition (CVD). The CVD method may be any appropriate CVD method known in the art. For example, the CVD method may be ALD, PECVD, RTCVD or LPCVD. In an exemplary embodiment, the contact etch resistant layer 24 is silicon carbide.

Next, the contact etch resistant layer 24 is anisotropically etched with a suitable etchant. The contact etch resistant layer 24 is etched down to expose the top of the gate electrode 18 and lateral surfaces of the semiconductor substrate 12, leaving the contact etch resistant spacers 24 shown in FIG. 3. The contact etch resistant spacers 24 may extend from the surface of the semiconductor substrate 12 to heights of between 800 and 1200 angstroms (Å) and thicknesses of between 200 and 400 angstroms (Å).

After the formation of the contact etch resistant spacers 24, the semiconductor device 10 is subjected to rapid thermal annealing (RTA). Exemplary RTA may be performed for between 5 and 15 seconds at a temperature of 1020-1050° C.

Now referring to FIG. 4 and Step S58, the liner layer 26 is formed on the semiconductor device 10. The liner layer 26 is formed of a nitrogen containing dielectric material. The liner layer 26 may be formed of a silicon nitride (SiₓN_{y}) material, for example. The liner layer 26 may be formed by a nitridation process as described below. The liner layer 26 may have a thickness of between 200 and 400 angstroms (Å), for example.

With reference to FIG. 5, the ILD layer 28 is formed on the liner layer 26 in Step S60. The ILD layer 28 is formed of a dielectric material, for example SiOₓ. The ILD layer 28 may be formed by a CVD process as described below. The ILD layer 28 may have a thickness of between 1000 and 4000 angstroms (Å), for example.

To form the liner layer 26 of silicon nitride, a nitrogen containing gas (NH₃) and silane are first provided to the CVD apparatus. When a suitable thickness of SiₓN_{y} has been deposited, the flow of the NH₃ gas is stopped, and the flow of oxygen gas is provided to the CVD apparatus, and continued until a suitable thickness of SiOₓ is deposited. It should be understood that the liner layer 26 and the ILD layer 28 may be deposited in separate apparatuses. Depositing nitride using conventional RTA techniques may also form the liner layer 26 of nitride.

Next, a photoresist layer 32 is formed on the ILD layer 28. The photoresist layer 32 is formed by a spin on coating process and patterned by photolithography process to form a contact mask as is known by those having ordinary skill in the art. The photoresist layer 32 may have a thickness of between 200 and 400 angstroms (A), for example.

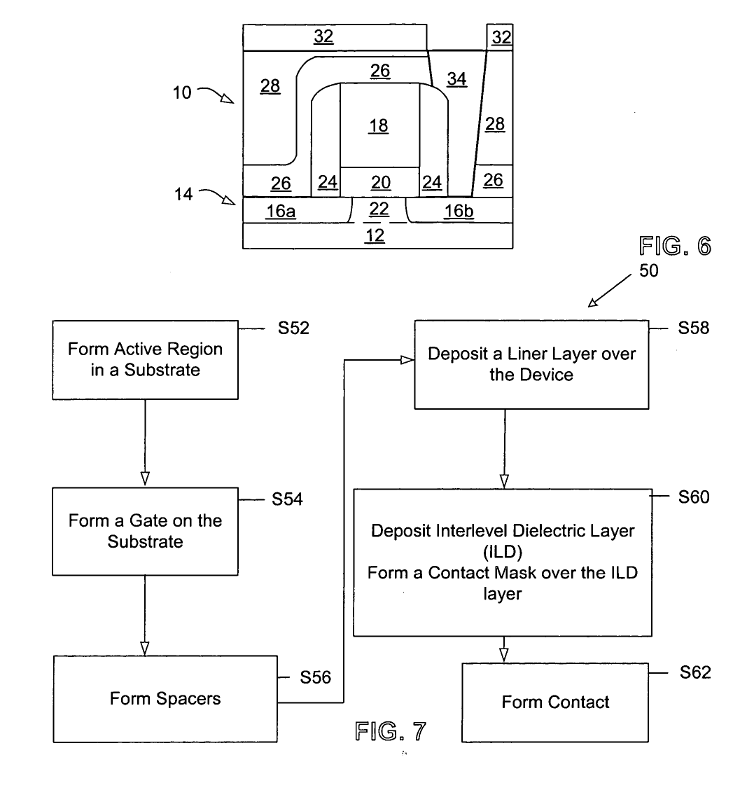

Next as shown in FIG. 6, the ILD layer 28 and the liner layer 26 are etched to form a contact aperture 34. An etchant species is selected that is selective between the material to be etched and the material which is to remain relatively unetched. In an embodiment, the etchant species is selected to etch the ILD layer 28 and the liner layer 26 while leaving the contact etch resistant spacer 24 relatively unetched.

Next in Step S62, tungsten, for example, is deposited into the aperture 32 to form the contact 30. The resulting semiconductor device 10 is shown in FIG. 1.

Subsequently, connections such as word lines may be formed using conventional techniques in order to establish electrical connections between the semiconductor device and other nodes (such as an I/O pad or Vss) of the device, as well as, a power supply or a ground, if desired. The formation of the connections is not shown.

### INDUSTRIAL APPLICABILITY

The present invention, by providing contact etch resistant spacers, overcomes the problem of partially etching through spacers during a contact etch step. Thus, the present invention enables further device scaling without adverse impact on device performance. That is, the contacts may be formed as close as possible to the vertical stack. The contact etch resistant spacers 24 also improve the device operation. Additionally, the contact etch resistant spacers 24 reduce the likelihood that a misaligned contact will adversely affect device performance.

The present invention is described above in terms of a common semiconductor device formed on a semiconductor substrate. Specifically, a field effect transistor (FET) formed on a semiconductor substrate is described. However, the present invention is not limited to this illustrative embodiment. The present invention may be applied to any semiconductor device in which a sidewall spacer is used. For example, the present invention may be used with a FLASH memory cell. Alternatively, the present invention may be used with an EEPROM FLASH memory cell. In another embodiment, the present invention may be used with a SONOS-type FLASH memory cell, such as the Mirror-Bit™ SONOS-type FLASH memory device available from AMD. Thus, it is to be understood that the present invention is not limited correspondingly in scope, but includes all changes, modifications and equivalents coming within the spirit and terms of the claims appended hereto. Additionally, although the flow diagram of FIG. 7 shows a specific procedural order, it is understood that the procedural order may differ from that which is depicted. For example, the procedural order of two or more blocks may be reordered relative to the order shown. Also, two or more blocks shown in succession in FIG. 7 may be processed concurrently or with partial concurrence.

1. A method of fabricating a semiconductor device comprising the steps of:
forming a gate dielectric layer on a semiconductor substrate;
forming a gate electrode over the gate dielectric layer wherein the gate electrode defines a channel interposed between source/drain regions formed within an active region of the semiconductor substrate; and
forming contact etch resistant spacers on sidewalls of the gate electrode and sidewalls of the gate dielectric layer,
the contact etch resistant spacers being of a non-silicon oxide and a non-nitride material.

2. The method according to claim 1, wherein the step of forming the contact etch resistant spacers includes the steps of:
forming a contact etch resistant layer on the sidewalls of the gate electrode, the sidewalls of the gate dielectric and portions of the upper surface of the semiconductor substrate; and
etching the contact etch resistant layer to form the contact etch resistant spacers.

3. The method of claim 2, further including the step of:
forming the contact etch resistant layer of at least one of silicon carbide and undoped silicon.

4. The method of claim 1, further including the step of:
forming a liner layer over the contact etch resistant spacers of at least one of SiₓN_{y} and SiOₓN_{y}.

5. The method of claim 1, further including the step of:
forming an interlevel dielectric layer over the contact etch resistant spacers of SiOₓ.

6. The method of claim 5, further including the step of:
forming a contact mask over the interlevel dielectric layer; and
etching a contact aperture to expose a source/drain region.

7. A semiconductor device comprising:
a dielectric layer interposed between a gate electrode and a semiconductor substrate; and
contact etch resistant spacers formed on sidewalls of the dielectric layer and sidewalls of the gate electrode,
the contact etch resistant spacers being of a non-silicon oxide and a non-nitride material.

8. A semiconductor device according to claim 7, wherein the contact etch resistant spacers are at least one of silicon carbide and undoped silicon.

9. The semiconductor device according to claim 8, wherein the contact etch resistant spacer is silicon carbide.

10. The semiconductor device according to claim 8, wherein the contact etch resistant spacer is undoped silicon.

11. The semiconductor device according to claim 7, further including a liner layer formed over the contact etch resistant spacers, wherein the liner layer is at least one of SiₓN_{y} and SiOₓN_{y}.

12. The semiconductor device according to claim 7, further including an interlevel dielectric layer (ILD) formed over the contact etch resistant spacers, wherein the ILD layer is SiOₓ.

13. A semiconductor device comprising:
a gate dielectric layer disposed over a semiconductor substrate;
a gate electrode formed on the gate dielectric layer defining a channel interposed between source/drain regions formed within an active region of the semiconductor substrate; and
contact etch resistant spacers formed on sidewalls of the dielectric layer and sidewalls of the gate electrode,
the contact etch resistant spacers being of a non-silicon oxide and a non-nitride material.

14. A semiconductor device according to claim 13, wherein the contact etch resistant spacer is at least one of silicon carbide and undoped silicon.

15. The semiconductor device according to claim 14, wherein the contact etch resistant spacer is silicon carbide.

16. The semiconductor device according to claim 14, wherein the contact etch resistant spacer is undoped silicon.

17. The semiconductor device according to claim 13, further including a liner layer formed over the contact resistant spacers, wherein the liner layer is at least one of SiₓN_{y} and SiOₓN_{y}.

18. The semiconductor device according to claim 17, wherein the liner layer is SiₓN_{y}.

19. The semiconductor device according to claim 17, wherein the liner layer is SiOₓN_{y}.

20. The semiconductor device according to claim 13, further including an interlevel dielectric layer (ILD) formed over the contact etch resistant spacers, wherein the ILD layer is SiOₓ.
